(19) United States
(12) Patent Application Publication
(10) Pub. No.: US 2024/0128351 A1
(43) Pub. Date: Apr. 18, 2024

(54) METHOD FOR MANUFACTURING SEMICONDUCTOR DEVICE

(71) Applicant: Mitsubishi Electric Corporation, Tokyo (JP)

(72) Inventors: Hiroyuki OKAZAKI, Tokyo (JP); Kohei NISHIGUCHI, Tokyo (JP)

(73) Assignee: Mitsubishi Electric Corporation, Tokyo (JP)

(21) Appl. No.: 18/547,084

(22) PCT Filed: Apr. 2, 2021
(86) PCT No.: PCT/JP2021/014292

§ 371 Date: Aug. 18, 2023

(51) Int. Cl. H01L 29/66; H01L 21/02; H01L 21/265

(52) U.S. Cl. CPC H01L 29/66431; H01L 21/0217; H01L 21/02274; H01L 21/0254; H01L 21/2654

(57) ABSTRACT

A method for manufacturing a semiconductor device of the present disclosure includes: ion-implanting impurities into a source-drain electrodes forming region where a source electrode and a drain electrode are to be formed on a nitride semiconductor layer formed on a substrate; forming a silicon nitride film on the surface of the nitride semiconductor layer by a plasma-enhanced chemical vapor deposition method, the silicon nitride film constituting a surface protecting sacrifice film and having a refractive index of 1.80 or more and less than 1.88 and a thickness of 100 nm or more and 500 nm or less; and heat-treating the nitride semiconductor layer on which the surface protecting sacrifice film is formed.

### TECHNICAL FIELD

The present application relates to a method for manufacturing a semiconductor device.

### BACKGROUND ART

In general, in semiconductor devices such as a high electron mobility transistor (HEMT) for high-frequency operation formed of compound semiconductors such as a nitride semiconductor, process for reducing resistance is performed on ohmic electrodes such as source-drain (SD) electrodes for the purpose of improving electrical characteristics. A typical example of the process for reducing resistance is an ion implantation process.

In the ion implantation process, an impurity region is formed in the nitride semiconductor layer by ion-implanting ionized impurities into the nitride semiconductor layer, and then an activation treatment is performed. The contact resistance between the nitride semiconductor layer and an electrode metal is greatly reduced by the ion implantation process.

Specifically, the activation treatment after the ion implantation is a heat treatment of the nitride semiconductor layer at a temperature of 1000° C. or higher. In the heat treatment of the nitride semiconductor layer, it is necessary to increase the heat treatment temperature to a temperature range close to epitaxial growth conditions of gallium nitride (GaN) or the like, for example. Since the surface of the nitride semiconductor layer is damaged during the high-temperature heat treatment, it has been common practice to reduce the damage by forming a cap film (a surface protecting sacrifice film) on the surface of the nitride semiconductor layer.

However, in the case of an oxide film such as silicon oxide (SiO) which is given as a material of a general surface protecting sacrifice film, it is difficult to completely suppress deterioration of reliability of the semiconductor device, deterioration of surface morphology of the nitride semiconductor layer, or the like as adverse effects due to the above-described activation treatment.

As a countermeasure against such a problem, for example, Patent Document 1 discloses a method for manufacturing a semiconductor device in which a thermally damaged surface layer of the nitride semiconductor is removed. Patent Document 2 discloses a method for manufacturing a semiconductor device in which conditions for forming the cap film (the surface protecting sacrifice film) during the heat treatment are defined.

### CITATION LIST

### Patent Document

Patent Document 1: Japanese Laid-Open Patent Publication No. 2017-079287
Patent Document 2: Japanese Laid-Open Patent Publication No. 2017-079288

### SUMMARY OF THE INVENTION

### Problem to be Solved by the Invention

A main heat treatment process at the time of manufacturing the HEMT formed of the nitride semiconductor is the ion implantation process which causes thermal damage at a temperature of 1000° C. or higher. Thermal damage to the nitride semiconductor layer caused during the ion implantation process, that is, deterioration of the surface morphology, can be simply suppressed by lowering the heat treatment temperature. However, there is another problem that contact resistance is deteriorated (increased) as the heat treatment temperature is lowered.

Further, for example, in the case where the reliability of the semiconductor device is secured by removing the damaged layer on the surface of the nitride semiconductor caused by the thermal damage after the heat treatment at the same heat treatment temperature as in the related art as disclosed in Patent Document 1, there is a concern that the number of manufacturing steps is increased and the nitride semiconductor layer under the gate electrode may be damaged, which may greatly affect the transistor characteristics. Furthermore, there is also a concern that a step portion is generated on the surface of the nitride semiconductor layer between the source electrode and the drain electrode with respect to the gate electrode, and this step portion causes unexpected electric field concentration on the surface of the nitride semiconductor layer, formation of a leak path, or the like.

When a film used as a thermal cap film (the surface protecting sacrifice film) disclosed in Patent Document 2 is formed by a plasma-enhanced chemical vapor deposition (PECVD), it is necessary to modify the film into a film having less hydrogen bonds such as a sputtered film formed by a sputtering method. For this purpose, according to Patent Document 2, it is necessary to add the heat treatment for reducing high damage requiring the heat treatment temperature in a temperature range of 800° C. to 1000° C. and the heat treatment time of 30 minutes to 60 minutes. Unfortunately, such heat treatment is accompanied by an increase in the number of manufacturing steps and an increase in unnecessary thermal damage to the nitride semiconductor layer, and thus there is a high possibility that the quality of the nitride semiconductor layer is rather deteriorated.

The present disclosure discloses a technique for solving the above-described problems, and an object of the present disclosure is to provide a manufacturing method capable of preventing deterioration of surface morphology of the nitride semiconductor layer and preventing formation of the damaged layer which are caused by the ion implantation process.

### Means to Solve the Problem

A method for manufacturing a semiconductor device of the present disclosure includes: ion-implanting impurities into a source-drain electrodes forming region where a source electrode and a drain electrode are to be formed on a nitride semiconductor layer formed on a substrate; forming a silicon nitride film on the surface of the nitride semiconductor layer by a plasma-enhanced chemical vapor deposition method, the silicon nitride film constituting a surface protecting sacrifice film and having a refractive index of 1.80 or more and less than 1.88 and a thickness of 100 nm or more and 500 nm or less; and heat-treating the nitride semiconductor layer on which the surface protecting sacrifice film is formed.

### Effect of the Invention

According to the method for manufacturing a semiconductor device disclosed in the present application, it is possible to suppress thermal damage to the nitride semiconductor layer, desorption of nitrogen atoms (N), or the like, thus providing an effect of preventing deterioration of the surface morphology of the nitride semiconductor layer and also preventing formation of the damaged layer.

### BRIEF DESCRIPTION OF THE DRAWING

FIG. 1 is a cross-sectional view showing a manufacturing process A in a method for manufacturing a semiconductor device according to Embodiment 1.

FIG. 2 is a cross-sectional view showing a manufacturing step B in the method for manufacturing a semiconductor device according to Embodiment 1.

FIG. 3 is a cross-sectional view showing a manufacturing step C in the method for manufacturing a semiconductor device according to Embodiment 1.

FIG. 4 is a cross-sectional view showing a manufacturing step D in the method for manufacturing a semiconductor device according to Embodiment 1.

FIG. 5 is a cross-sectional view showing a manufacturing step E in the method for manufacturing a semiconductor device according to Embodiment 1.

FIG. 6 is a cross-sectional view showing a manufacturing step F in the method for manufacturing a semiconductor device according to Embodiment 1.

FIG. 7 is a cross-sectional view showing a manufacturing step G in the method for manufacturing a semiconductor device according to Embodiment 1.

FIG. 8 shows the relationship between the thickness of the silicon nitride film and the defect density on the surface of the nitride semiconductor layer in the method for manufacturing a semiconductor device according to Embodiment 1.

FIG. 9 is a cross-sectional view showing a manufacturing step E-1 of a method for manufacturing a semiconductor device according to Embodiment 2.

FIG. 10 is a cross-sectional view showing a manufacturing step E-2 of the method for manufacturing a semiconductor device according to Embodiment 2.

### DESCRIPTION OF EMBODIMENTS

### Embodiment 1

A method for manufacturing a semiconductor device according to Embodiment 1 will be described below.

The method for manufacturing a semiconductor device according to Embodiment 1 includes at least following manufacturing steps A to G.

In addition, the method for manufacturing a semiconductor device according to Embodiment 1 particularly relates to an ion implantation process which is one of the manufacturing processes having the highest temperature among all the manufacturing processes for the semiconductor device which is a target of the present disclosure.

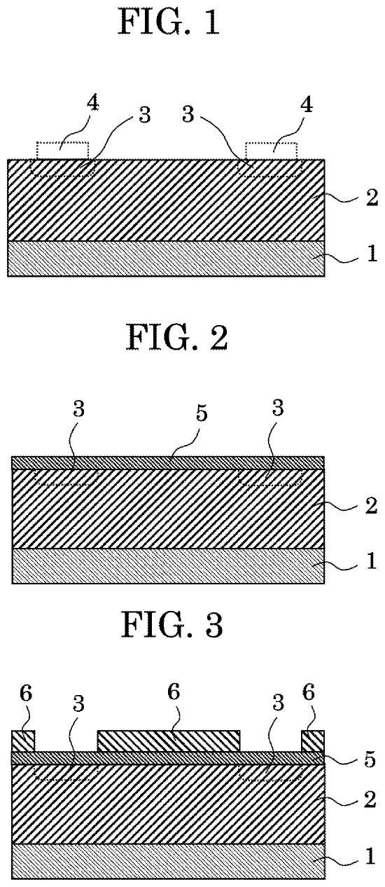

The method for manufacturing a semiconductor device according to Embodiment 1 will be described with reference to FIGS. 1 to 7. Noted that FIGS. 1 to 7 show a cross-sectional structure around a gate electrode in an active layer region of a nitride semiconductor transistor 100 as an example of the semiconductor device composed of a nitride semiconductor.

(Manufacturing Step A)

First, a nitride semiconductor layer 2 including a buffer layer, a channel layer, an electron supply layer, and a cap layer (none of which are shown) constituting the semiconductor device is epitaxially grown on a substrate 1. FIG. 1 shows a cross section after the epitaxial growth. Specific examples of the substrate 1 include silicon (Si), silicon carbide (SiC), GaN, and sapphire substrates. In each of the following manufacturing steps, a case where a GaN on SiC substrate is used as the substrate 1 will be described.

As described above, the buffer layer, the channel layer, the electron supply layer, and the cap layer are all composed of the nitride semiconductor. Specific examples of the nitride semiconductor include GaN, aluminum gallium nitride (AlGaN) or the like.

In the cross-sectional view shown in FIG. 1, a portion where the ion implantation region 3 is to be formed and a portion where a source electrode forming region and a drain electrode forming region (hereinafter referred to as a source-drain electrodes forming region 4) are to be formed are indicated by dotted lines. The area of the ion implantation region 3 is set in advance to be larger than the area of the source-drain electrodes forming region 4.

The reason for such setting is that the most dominant portion among the contact resistance components of the semiconductor device is the end portion of the source-drain electrodes forming region 4, that is, the edge thereof, and it is important that at least the end portion is ion-implanted in order to obtain good contact resistance.

(Manufacturing Step B)

Next, as shown in the cross-sectional view of FIG. 2, a through film for ion implantation 5 that functions to protect the surface of the nitride semiconductor layer 2 during the ion implantation is formed on the GaN on SiC substrate 1. A nitride film such as a silicon nitride (SiN) film or an oxide film such as a SiO film may be formed by a film forming method (film forming apparatus) of the through film for ion implantation 5 such as a sputtering method or a PECVD method. In one example of the method for manufacturing a semiconductor device according to Embodiment 1, the SiN film is used as the through film for ion implantation 5.

(Manufacturing Step C)

Next, as shown in the cross-sectional view of FIG. 3, on the surface of the through film for ion implantation 5, a resist is patterned to form a resist mask 6 in which only the ion implantation region 3 is opened. After the resist mask 6 is formed, the ion implantation is performed. In the ion implantation, ionized impurities such as Si are irradiated. The impurities penetrating through the through film for ion implantation 5 by the ion implantation reaches an inside of the nitride semiconductor layer 2 to form the ion implantation region 3.

(Manufacturing Step D)

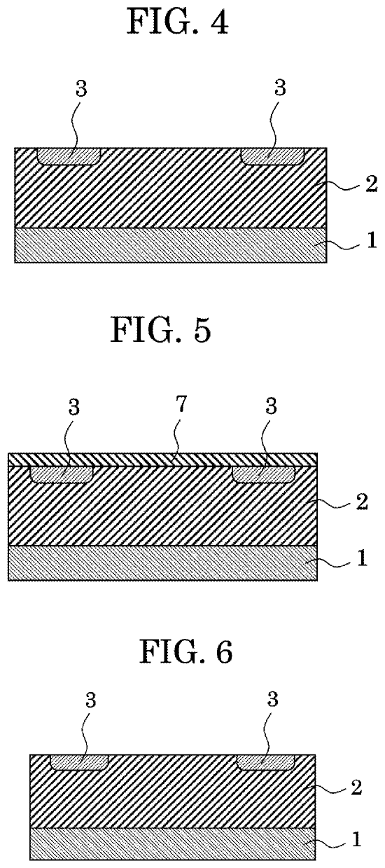

As shown in the cross-sectional view of FIG. 4, after the ion implantation region 3 is formed, the resist mask 6 and the through film for ion implantation 5 are removed. At the time of the removal, a wet etching process with hydrofluoric acid or the like as an etchant is applied to remove the resist mask 6, which is cured during the ion implantation, together with the through film for ion implantation 5. Other removal methods such as dry etching may also be used.

(Manufacturing Step E)

Next, as shown in the cross-sectional view of FIG. 5, a surface protecting sacrifice film 7 is formed on the surface of the nitride semiconductor layer 2 before performing the activation heat treatment of the impurities in the ion implantation region 3. The surface protecting sacrifice film 7 functions to suppress thermal damage to the surface of the nitride semiconductor layer 2. As a method of forming the surface protecting sacrifice film 7, the PECVD method is applied. This is because a film formed by the PECVD method generally has lower stress than a film formed by the sputtering method.

The SiN film is used as the material of the surface protecting sacrifice film 7. This is because the SiN film functions to suppress desorption of nitrogen atoms (N) from the nitride semiconductor layer 2 caused by the damage during the heat treatment. With respect to the film quality of the SiN film as the surface protecting sacrifice film 7, it is preferable that the SiN film is N-rich with respect to stoichiometry, that is, the SiN film in which nitrogen (N) is excessive. When the film quality of the surface protecting sacrifice film 7 is defined as a refractive index, it is preferable that the refractive index of the N-rich SiN film is less than 1.88 which is equal to the refractive index of the stoichiometric SiN film.

On the other hand, if the SiN film is excessively rich in N, nitrogen (N) is too excessive, so that the function as the surface protecting sacrifice film 7 is deteriorated. From this point of view, the refractive index of the SiN film is preferably 1.80 or more. Consequently, the refractive index of the SiN film is preferably 1.80 or more and less than 1.88.

The thickness of the surface protecting sacrifice film 7 is preferably 100 nm or more. This is because as the amount of nitrogen atoms (N) desorbed from the surface of the nitride semiconductor layer 2 by the heat treatment at a high temperature increases, it becomes necessary to increase the volume of the surface protecting sacrifice film 7 functioning as the suppression film. Consequently, the thickness of the surface protecting sacrifice film 7 needs to be at least 30 nm or more even when the heat treatment temperature during the heat treatment is 1000° C. or less. This is also because the heat treatment temperature during the heat treatment in the ion implantation process according to Embodiment 1 is a very high temperature of 1000° C. to 1200° C.

On the other hand, the thickness of the surface protecting sacrifice film 7 is preferably 500 nm or less. If the film thickness of the surface protecting sacrifice film 7 is made thicker than necessary, the time required for film formation becomes longer, and the amount of film forming material used also increases, resulting in a problem that the manufacturing cost increases. Therefore, the thickness of the surface protecting sacrifice film (the SiN film) 7 is preferably 100 nm or more and 500 nm or less.

In addition, in order to achieve the same effect as the activation rate obtained by the heat treatment under the treatment conditions of the heat treatment temperature of 1200° C. and the heat treatment time of 5 minutes, for example, when the heat treatment temperature is 1150° C., it is necessary to apply a heat history for 10 minutes or more, and the treatment conditions of the heat treatment may be changed to some extent in accordance with the desired activation rate.

After the surface protecting sacrifice film 7 is formed, the heat treatment is performed to activate the impurities in the ion implantation region 3. As the heat treatment, by setting the heat treatment temperature in a range of 1000° C. to 1200° C., the impurities ion-implanted into the nitride semiconductor layer 2 are activated, and thus good contact resistance is obtained. In general, a higher heat treatment temperature provides a lower resistance contact, that is, a better electrical connection.

In general, the damage to the nitride semiconductor layer 2 increases with thermal history such as an increase in heat treatment temperature and an increase in heat treatment time during the heat treatment, and thus deterioration of surface morphology due to desorption of nitrogen atoms (N) from the surface of the nitride semiconductor layer 2, an increase in potential crystal defects in the epitaxial crystal growth layer, that is, in the nitride semiconductor layer 2, or the like occur. However, according to the method for manufacturing a semiconductor device according to Embodiment 1, by applying the above-described surface protecting sacrifice film 7 in the ion implantation process, the occurrence of the above-described problems can be significantly suppressed.

(Manufacturing Step F)

After the heat treatment, the surface protecting sacrifice film 7 is removed. FIG. 6 is a cross-sectional view after the surface protecting sacrifice film 7 is removed. The surface protecting sacrifice film 7 can be removed by wet etching. Although the surface protecting sacrifice film 7 can be removed by dry etching, dry etching of the active layer region is not recommended because there is a concern that the surface of the nitride semiconductor layer 2 may be damaged.

(Manufacturing Step G)

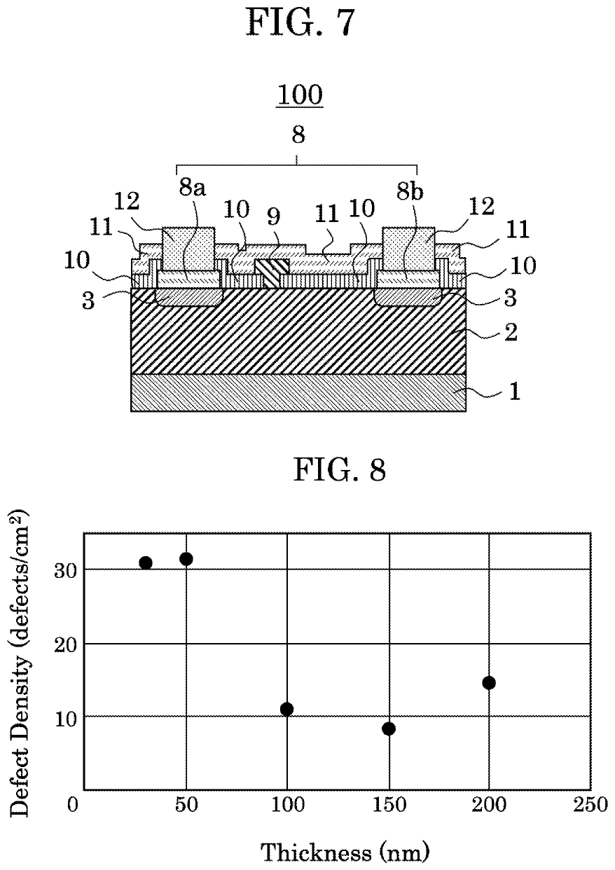

After the above-described manufacturing steps A to F are performed, transistor forming steps such as formation of a source electrode 8a and a drain electrode 8b (hereinafter, the source electrode 8a and the drain electrode 8b are collectively referred to as source-drain electrodes 8), formation of a gate electrode 9, formation of a first gate protective film 10 (a first gate passivation) and a second gate protective film 11 (a second gate passivation), and formation of wiring layers 12 are performed by a general manufacturing method. FIG. 7 is a cross-sectional view of the nitride semiconductor transistor 100 as an example of a semiconductor device.

FIG. 8 shows the relationship between the thickness of the SiN film used as the surface protecting sacrifice film 7 and the defect density on the surface of the nitride semiconductor layer 2 in the method for manufacturing a semiconductor device according to Embodiment 1. Noted that the refractive index of the SiN film is 1.85. As can be seen from FIG. 8, when the thickness of the SiN film is 50 nm or less, the defect density is as high as 31.0 defects/cm 2 or more.

On the other hand, when the thickness of the SiN film is 100 nm or more and 150 nm or less, the defect density is as low as 10.6 defects/cm 2 or less, and even when the thickness of the SiN film is 200 nm, the defect density is maintained as low as 14.3 defects/cm 2.

As described above, according to the method for manufacturing a semiconductor device according to Embodiment 1, the surface protecting sacrifice film made of the SiN film having the refractive index of 1.80 or more and less than 1.88 and the thickness of 100 nm or more and 500 nm or less is formed on the nitride semiconductor layer after the ion implantation, and then the heat treatment after the ion implantation is performed. This makes it possible to suppress the thermal damage to the nitride semiconductor layer, desorption of nitrogen atoms (N), or the like, thus providing an effect of preventing deterioration of the surface morphology of the nitride semiconductor layer and also preventing formation of the damaged layer.

According to the above-described effect, it is possible to perform the activation heat treatment after the ion implantation at a higher temperature (or to secure a temperature margin) than in related art, thus providing an effect that the contact resistance of the semiconductor device can be reduced. Further, it is possible to reduce the appearance defect rate of the semiconductor device, to prevent the initial failure operation thereof, and to improve the reliability.

### Embodiment 2

A method for manufacturing a semiconductor device according to Embodiment 2 is different from the method for manufacturing a semiconductor device according to Embodiment 1 in that the surface protecting sacrifice film 17 is composed of two layers of a lower surface protecting sacrifice film 17a in contact with the nitride semiconductor layer 2 and an upper surface protecting sacrifice film 17b on the front surface side.

The method for manufacturing a semiconductor device according to Embodiment 2 will be described below. Noted that since the manufacturing steps A to D, F, and G are the same as those in the method for manufacturing a semiconductor device according to Embodiment 1, description thereof will be omitted.

(Production Step E-1)

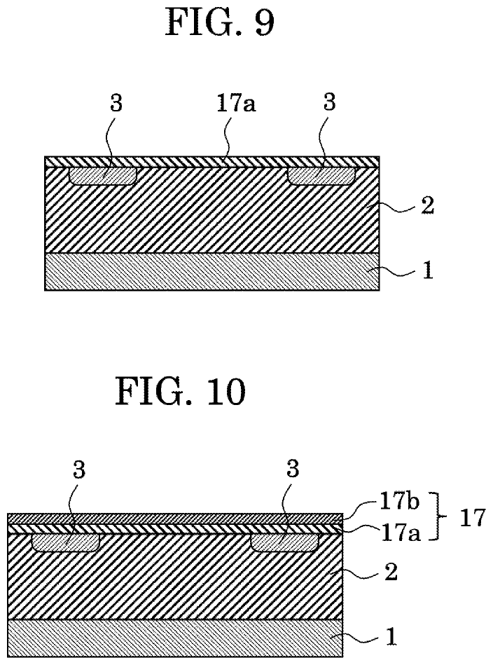

As shown in the cross-sectional view of FIG. 9, before the activation heat treatment of the impurities in the ion implantation region 3 is performed, the lower surface protecting sacrifice film 17a of two layer surface protecting sacrifice film 17 is first formed on the surface of the nitride semiconductor layer 2. The lower surface protecting sacrifice film 17a functions to suppress the thermal damage to the surface of the nitride semiconductor layer 2.

As a method of forming the lower surface protecting sacrifice film 17a, a PECVD method is applied. Further, a SiN film is used as the material of the lower surface protecting sacrifice film 17a. This is because the SiN film functions to suppress desorption of nitrogen atoms (N) from the nitride semiconductor layer 2 caused by the damage during the heat treatment. The SiN film constituting the lower surface protecting sacrifice film 17a has the refractive index of 1.80 or more and less than 1.88 and the thickness of 30 nm or more.

(Production Step E-2)

Next, as shown in the cross-sectional view of FIG. 10, the upper surface protecting sacrifice film 17a is formed on the surface of the lower surface protecting sacrifice film 17b. As described above, the surface protecting sacrifice film 17 is composed of two layers of the lower surface protecting sacrifice film 17a and the upper surface protecting sacrifice film 17b.

The upper surface protecting sacrifice film 17b may be a film formed by any film forming method. Specific examples of the method for forming the upper surface protecting sacrifice film 17b include a sputtering method, an atomic layer deposition (ALD) method or the like. Noted that the film forming method is not limited to above-described ones in the present disclosure.

Examples of the material constituting the upper surface protecting sacrifice film 17b include the nitride film and the oxide film or the like. Noted that the material is not limited to these films, and any film may be applied without any problem. For example, an aluminum nitride (AlN) film formed by the sputtering method, a SiO film formed by the PECVD method, an aluminum oxide (AlO) film formed by the ALD method, or the like can be applied without any problem. However, since the upper surface protecting sacrifice film 17b is excessively stressed with respect to the lower surface protecting sacrifice film 17a, there is a limitation that film peeling or the like does not occur.

As described above, the thickness of the lower surface protecting sacrifice film 17a needs to be 30 nm or more. The total thickness of the surface protecting sacrifice film 17 needs to be 100 nm or more and 500 nm or less. Such a film thickness is necessary for the surface protecting sacrifice film 17 to function as a film for suppressing the desorption of nitrogen atoms (N) from the surface of the nitride semiconductor layer 2 due to the high-temperature treatment, and on the other hand, if the film thickness is thicker than necessary, the manufacturing cost increases.

As described above, in the method for manufacturing a semiconductor device according to Embodiment 2, the lower surface protecting sacrifice film is formed of the SiN film having the refractive index of 1.80 or more and less than 1.88 and the thickness of 30 nm or more, and the total thickness of the surface protecting sacrifice film including the upper surface protecting sacrifice film is 100 nm or more and 500 nm or less, and the heat treatment is performed after the ion implantation, thus providing an effect of suppressing the thermal damage to the nitride semiconductor layer and the desorption of nitrogen atoms (N), and also preventing deterioration of the surface morphology of the nitride semiconductor layer. With these effects, it is further possible to reduce the appearance defect rate of the semiconductor device, to prevent the initial failure operation of the semiconductor device, and to improve the reliability of the semiconductor device.

### Embodiment 3

A method for manufacturing a semiconductor device according to Embodiment 3 is different from the method for manufacturing a semiconductor device according to Embodiment 1 in that a specific metal material is used as the material of the source-drain electrodes 8.

The method for manufacturing a semiconductor device according to Embodiment 3 will be described below. Noted that since the manufacturing steps A to F are the same as those of the method for manufacturing a semiconductor device according to Embodiment 1, description thereof will be omitted.

(Production Step G-1)

After the above-described manufacturing steps A to F are performed, transistor forming steps such as formation of the source-drain electrodes 8, formation of a gate electrode 9, formation of a first gate protective film 10 (a first gate passivation) and a second gate protective film 11 (a second gate passivation), and formation of wiring layers 12 or the like are performed by a general manufacturing method.

In the formation of the source-drain electrodes 8, a metal material such as titanium (Ti), niobium (Nb), platinum (Pt), gold (Au) or the like, or a combination of two or more of these metal materials, which does not include an aluminum (Al) based material, is used as the electrode material of the source-drain electrodes 8.

In the source-drain electrodes 8 to which the Al-based material is applied, even when the above-described ion implantation process is not performed, by using Al having high reactivity as the electrode material, Al is mixed with the underlying nitride semiconductor layer 2 by the heat treatment (ohmic sintering), so that a good ohmic contact resistivity can be obtained.

However, Al is mixed violently with not only the underlying nitride semiconductor layer 2 but also the metal material for forming the source-drain electrodes other than Al, and there is a concern that surface roughness of the source-drain electrodes 8, contact failure, or the like occur. Therefore, it is preferable that the Al-based material is not included as the metal material constituting the source-drain electrodes 8, that is, the Al-based material is excluded. This is because, when the above-described ion implantation process is performed, if the Al-based material is selected as the electrode material of the source-drain electrodes 8, it is difficult to avoid the surface roughness of the nitride semiconductor layer 2 itself.

In the method for manufacturing a semiconductor device according to Embodiment 3, even when Al is not used as the metal material of the source-drain electrodes 8, electrode roughness in the source-drain electrodes 8 can be avoided by performing the above-described ion implantation process. Furthermore, by performing the above-described ion implantation process, it is also possible to avoid the surface roughness of the nitride semiconductor layer 2.

Therefore, in the method for manufacturing a semiconductor device according to Embodiment 3, as the metal material of the source-drain electrodes 8, the metal material such as titanium (Ti), niobium (Nb), platinum (Pt), gold (Au) or the like, which does not include an Al-based material, or the combination of two or more of these metal materials is used.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 substrate
2 nitride semiconductor layer
3 ion implantation region
4 source-drain electrodes forming region
5 through film for implantation
6 resist mask
7, 17 surface protecting sacrifice film
8 source-drain electrodes
8a source electrode
8b drain electrode
9 gate electrode
10 first gate protective film
11 second gate protective film
12 wiring layer
17a lower surface protecting sacrifice film
17b upper surface protecting sacrifice film
100 nitride semiconductor transistor

1. A method for manufacturing a semiconductor device comprising:
ion-implanting impurities into a source-drain electrodes forming region where a source electrode and a drain electrode are to be formed on a nitride semiconductor layer formed on a substrate;
forming a silicon nitride film on the surface of the nitride semiconductor layer by a plasma-enhanced chemical vapor deposition method, the silicon nitride film constituting a surface protecting sacrifice film and having a refractive index of 1.80 or more and less than 1.88 and a thickness of 100 nm or more and 500 nm or less; and
heat-treating the nitride semiconductor layer on which the surface protecting sacrifice film is formed.

2. A method for manufacturing a semiconductor device comprising:
ion-implanting impurities into a source-drain electrodes forming region where a source electrode and a drain electrode are to be formed on a nitride semiconductor layer formed on a substrate;
forming a silicon nitride film on the surface of the nitride semiconductor layer by a plasma-enhanced chemical vapor deposition method, the silicon nitride film constituting a lower surface protecting sacrifice film which is one layer of a surface protecting sacrifice film including two layers of an upper surface protecting sacrifice film and the lower surface protecting sacrifice film, the lower surface protecting sacrifice film having a refractive index of 1.80 or more and less than 1.88 and a thickness of 30 nm or more;
forming the upper surface protecting sacrifice film stacked on the lower surface protecting sacrifice film and having a total thickness of 100 nm or more and 500 nm or less with the lower surface protecting sacrifice film; and
heat-treating the nitride semiconductor layer on which the surface protecting sacrifice film is formed.

3. The method for manufacturing a semiconductor device according to claim 1, wherein a heat treatment temperature during heat treatment is 1000° C. or more and 1200° C. or less.

4. The method for manufacturing a semiconductor device according to claim 1, wherein the source electrode and the drain electrode are made of an electrode material excluding aluminum.

5. The method for manufacturing a semiconductor device according to claim 1, wherein the electrode material is any one of titanium, niobium, platinum, and gold, or a combination of two or more thereof.

6. The method for manufacturing a semiconductor device according to claim 1, wherein the surface protecting sacrifice film is removed by wet etching.

7. The method for manufacturing a semiconductor device according to claim 2, wherein a heat treatment temperature during heat treatment is 1000° C. or more and 1200° C. or less.

8. The method for manufacturing a semiconductor device according to claim 2, wherein the source electrode and the drain electrode are made of an electrode material excluding aluminum.

9. The method for manufacturing a semiconductor device according to claim 2, wherein the electrode material is any one of titanium, niobium, platinum, and gold, or a combination of two or more thereof.

10. The method for manufacturing a semiconductor device according to claim 2, wherein the surface protecting sacrifice film is removed by wet etching.
